(19) United States
(12) Patent Application Publication
(10) Pub. No.: US 2008/0169555 A1
(43) Pub. Date: Jul. 17, 2008

(54) ANCHOR STRUCTURE FOR AN INTEGRATED CIRCUIT

(75) Inventors: Roden R. Topacio, Markham (CA); Vincent K. Chan, Richmond Hill (CA)

Correspondence Address: ADVANCED MICRO DEVICES, INC.;C/O VEDDER PRICE P.C., 222 N.LASALLE STREET, CHICAGO, IL, 60601, US

(73) Assignee: ATI Technologies ULC, Markham (CA)

(21) Appl. No.: 11/623,532

(22) Filed: Jan. 16, 2007

(51) Int. Cl. H01L 23/48; H01L 23/12; H01L 21/02

(52) U.S. Cl. 257/701; 438/125; 257/737; 257/E23.005; 257/E21.002; 257/E23.021

(57) ABSTRACT

An integrated circuit product includes a die and an insulation layer. The insulation layer is operatively coupled to the die. The insulation layer includes a plurality of bump apertures. The insulation layer also includes an underfill anchor structure. Methods for making such an integrated circuit product are also described.

### FIELD OF THE INVENTION

The present invention generally relates to semiconductor fabrication, and more particularly to a method and apparatus for attaching an insulation layer of a die to another material.

### BACKGROUND OF THE INVENTION

A flip-chip is a semiconductor device typically in the form of a die mounted directly onto a substrate (e.g., a carrier) in a “face-down” manner. An electrical connection is achieved through conductive bumps attached to the surface of the die. During mounting, the chip is flipped on the substrate (hence the name “flip-chip”), with the bumps being positioned on respective target locations. Flip-chips are typically smaller than conventional chips because they do not require wirebonds.

Referring now to FIGS. 1A and 1B, a portion of a flip-chip 10 according to the prior art is depicted. FIG. 1A is an exemplary cross section view of a portion of the flip-chip 10. FIG. 1B is an exemplary top view of a portion of the flip-chip 10. The flip-chip 10 includes a die 12, an insulation layer 14, an under bump metal (UBM) 16, a conductive bump 18, an underfill material 20, and a substrate 22. The die 12 may include an electronic circuit. The insulation layer 14 is a dielectric material (typically polyimide or other material) that is applied to the die 12. The insulation layer 14 includes bump aperture 24 for each conductive bump 18. The insulation layer 14 serves as a stress buffer, a planarizing medium, and a passivation layer.

The conductive bump 18 is electrically coupled to the die 12 and provides electrical contact from the die 12 to the substrate 22. More specifically, the UBM 16 is operatively coupled to the die 12 through the bump aperture 24 and the conductive bump 18 is operatively coupled to the UBM 16. The conductive bump 18 is also operatively coupled to the substrate 22.

The underfill material 20, which is typically a non-electrically conductive adhesive, is used to fill in the gaps between the insulation layer 14 and the substrate 22. The underfill material 20 adheres to the insulation layer 14 and to the substrate 22. The underfill material 20 protects the conductive bumps 18 from thermal expansion mismatches between the die 12 and the substrate 22. The underfill material 20 also serves to protect the flip-chip 10 from moisture, ionic contaminants, radiation, and hostile operating environments such as thermal and mechanical conditions (i.e., shock, vibration, etc.).

When the flip-chip 10 is exposed to stress, the adhesive bond between the insulation layer 14 and the underfill material 20 may weaken. The weakened adhesive bond may result in a delamination between the insulation layer 14 and the underfill material 20, which is undesirable.

One method used to try to overcome this problem involves treating a surface 26 of the insulation layer 14 such as by plasma etching or any other suitable method. Treating the surface 26 results in a rougher surface area of the insulation layer by introducing submicron valleys or other configurations, which aids in adhering the insulation layer 14 to the underfill material 20. However, this method is still susceptible to delamination under certain stress conditions.

In another method, adhesive properties of the underfill material 20 may be altered to increase bonding properties. However, this method still relies on an adhesive surface bond and is still susceptible to delamination under certain stress conditions.

In yet another method, the surface 26 of the insulation layer 14 may be cleaned with an additional cleaning process during manufacture. However, this method may increase manufacturing costs of the flip-chip 10. Additionally, this method still relies on an adhesive surface bond and is still susceptible to delamination under certain stress conditions.

It is therefore desirable to provide, among other things, an integrated circuit having an insulation layer that attaches to an underfill material in an improved manner.

### BRIEF DESCRIPTION OF THE DRAWINGS

The invention will be more readily understood in view of the following description when accompanied by the below figures and wherein like reference numerals represent like elements, wherein:

FIG. 1A is an exemplary cross section of a portion of a flip-chip according to the prior art;

FIG. 1B is an exemplary top view of a portion of a flip-chip according to the prior art;

FIG. 2 is a cross section of a flip-chip having one example of an insulation layer with an anchor structure in accordance with one embodiment of the invention;

FIG. 3 is an exemplary top view of the flip-chip of FIG. 2;

FIG. 4 is a second exemplary top view of the flip-chip of FIG. 2;

FIG. 5 is a second exemplary cross section of a flip-chip having an insulation layer with an anchor structure;

FIG. 6 is a flowchart that depicts exemplary steps that may be taken to make a flip-chip having an insulation layer with an anchor structure;

FIG. 7 is a flowchart the depicts exemplary steps that may be taken to make the flip-chip of FIG. 2;

FIG. 8 is a flowchart the depicts exemplary steps that may be taken to make the flip-chip of FIG. 5; and

FIG. 9 is a functional block diagram of an exemplary device that implements a flip-chip having an insulation layer with an anchor structure.

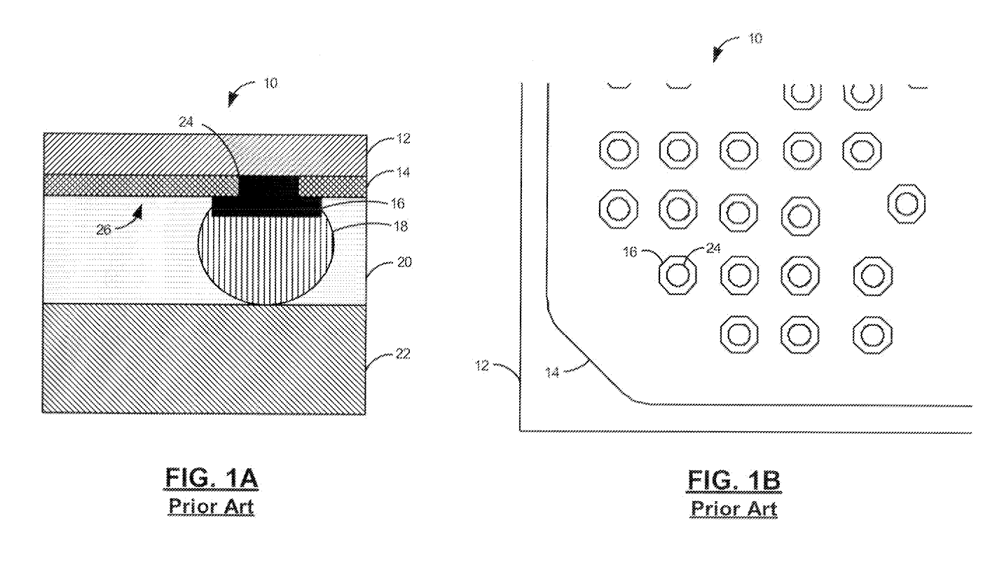

### DETAILED DESCRIPTION

In one example, an integrated circuit (IC) product includes a die and an insulation layer. The insulation layer is operatively coupled to the die. The insulation layer includes a plurality of bump apertures. The insulation layer also includes an underfill anchor structure. The underfill anchor structure is defined by locatable apertures/and or protrusion structures as described below. They may be locatable by using masking techniques, etching techniques or other suitable techniques. The locatable apertures and/or protrusions have a depth of multiple microns. The underfill anchor structure includes aperture and/or protrusion structures that are configured in suitable locations and are defined to be of a desired size, shape and configuration. For example, they may be apertures having a conical shape, cylindrical shape or any other suitable configuration as desired. Among other advantages, the underfill anchor structure is a definable structure that can afford improved quality by providing consistent locations and configurations of anchoring mechanisms as compared to surfacing roughing techniques. The anchor structure may also help reduce delamination. Other advantages will be recognized by those ordinarily skilled in the art.

In one example, the IC product includes an underfill material mechanically attached to the underfill anchor structure.

In one example, the underfill anchor structure includes at least one aperture defined by the insulation layer. In another example, the underfill anchor structure includes a protrusion and/or a recess.

In one example, IC product includes a dummy material operatively coupled between the die and the insulation layer. The dummy material defines the underfill anchor structure.

In one example, the underfill anchor structure is configured along at least a portion of a perimeter of the insulation layer. In another example, the underfill anchor structure is configured around the plurality of bump apertures.

In one example, a process of making an integrated circuit product includes providing a die and adding an insulation layer to the die. The insulation layer includes a plurality of bump apertures. The insulation layer also includes an underfill anchor structure.

In one example, the plurality of bump apertures and/or the underfill anchor structure is formed by removing a portion of the insulation layer. In another example, the portion of the insulation layer is removed by applying a mask to the insulation layer that defines the plurality of bump apertures and/or the anchor structure. Electromagnetic radiation is exposed to the mask and to the insulation layer. The insulation layer is developed and cured. Portions of the insulation layer unexposed to the electromagnetic radiation through the mask are removed.

In one example, the underfill anchor structure includes at least one aperture defined by the insulation layer. In another example, the underfill anchor structure includes a protrusion and/or a recess.

In one example, the underfill anchor structure is configured along at least a portion of a perimeter of the insulation layer. In another example, the underfill anchor structure is configured around the plurality of bump apertures.

In one example, a dummy material is operatively coupled to the die surface prior to adding the insulation layer. The dummy material defines the underfill anchor structure.

In one example, a plurality of conductive bumps are operatively coupled to the die through the plurality of bump apertures. A substrate is operatively coupled to the plurality of conductive bumps. Gaps between the die and the substrate are filled an underfill material. The underfill material is mechanically attached to the underfill anchor structure.

In one example, an integrated circuit product includes a die, an insulation layer, a plurality of conductive bumps, a substrate, and an underfill material. The insulation layer is operatively coupled to the die. The insulation layer includes a plurality of bump apertures and an underfill anchor structure. The plurality of conductive bumps are operatively coupled to the die through the plurality of bump apertures. The substrate is operatively coupled to the plurality of conductive bumps. The underfill material fills in gaps between the die and the substrate. The underfill material is mechanically attached to the underfill anchor structure.

In one example, the underfill anchor structure includes at least one aperture defined by the insulation layer. In another example, the underfill anchor structure includes a protrusion and/or a recess.

In one example, the underfill anchor structure is configured along at least a portion of a perimeter of the insulation layer. In another example, the underfill anchor structure is configured around the plurality of bump apertures.

In one example, a device includes an integrated circuit (IC) product. The IC product includes a die, an insulation layer, a plurality of conductive bumps, a substrate, and an underfill material. The insulation layer is operatively coupled to the die. The insulation layer includes a plurality of bump apertures and an underfill anchor structure. The plurality of conductive bumps are operatively coupled to the die through the plurality of bump apertures. The substrate is operatively coupled to the plurality of conductive bumps. The underfill material fills in gaps between the die and the substrate. The underfill material is mechanically attached to the underfill anchor structure.

In one example, a display is operatively coupled to the IC product. The die includes a processor.

As used herein, the term module, circuit and/or stage can include any suitable electronic circuit, including but not limited to, one or more processors (e.g., cores, shared, dedicated, or group of processors such as but not limited to microprocessors, graphics processors, DSPs, or central processing units) and memory that execute one or more software or firmware programs, a combinational logic circuit(s), analog and digital circuits, and/or other suitable components that provide the described functionality.

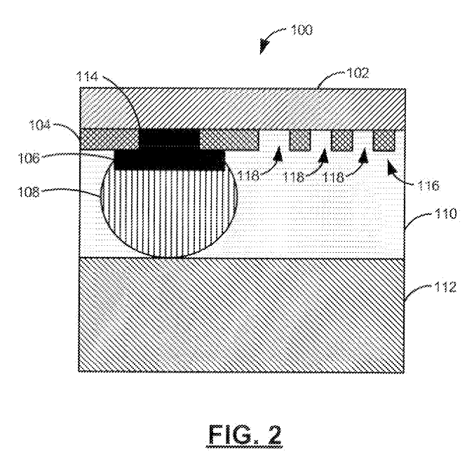

Referring now to FIG. 2, an exemplary cross section of a portion of a flip-chip 100 is depicted. The flip chip 100 includes a die 102, an insulation layer 104, an under bump metal (UBM) 106, a conductive bump 108, an underfill material 110, and a substrate 112. The die 102, insulation later 104, UBM 106, and conductive bump 108 are often referred to collectively as a bumped die.

The die 102 may include one or more electronic circuits. The insulation layer 104 is a dielectric material, typically polyimide, that is applied to the die 102. In some embodiments, the insulation layer 104 is 5-6 micrometers thick. The insulation layer 104 serves as a stress buffer, a planarizing medium, and a passivation layer. The insulation layer 104 includes a bump aperture 114 and an anchor structure 116. The anchor structure 116 may comprise apertures 118 defined by the insulation layer 104.

The conductive bump 108, such as an Sn/Pb eutectic bump or other known material, is operatively coupled to the die 102 and the substrate 112. More specifically, the UBM 106 is coupled to the die 102 through the bump aperture 114 using known techniques and the conductive bump 108 is coupled to the UBM 106 as known in the art.

The underfill material 110, which is typically a non-electrically conductive adhesive such as Namics 8439, is used to fill in gaps between the insulation layer 104 and the substrate 112. The underfill material 110 protects the conductive bumps 108 from thermal expansion mismatches between the die 102 and the substrate 112. The underfill material 110 also serves to protect the flip-chip 100 from moisture, ionic contaminants, radiation, and hostile operating environments such as thermal and mechanical conditions (i.e., shock, vibration, etc.).

The underfill material 110 attaches to the insulation layer 104. More specifically, the anchor structure 116 mechanically attaches to the underfill material 110 creating a mechanical lock. In addition to the mechanical lock, the insulation layer 104 and underfill material 110 are also attached by an adhesive bond from the underfill material. By combining the mechanical lock and the adhesive bond, the flip-chip 100 has a stronger structure than conventional flip-chips making it less susceptible to delamination.

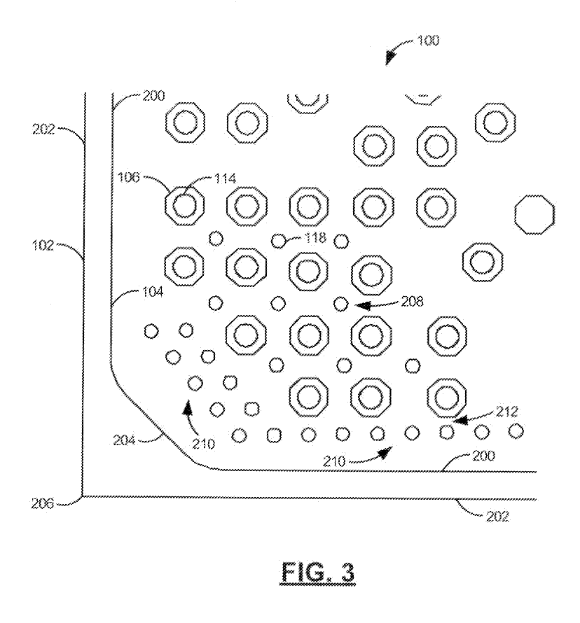

Referring now to FIG. 3, an exemplary top view of the flip-chip 102 is depicted. In some embodiments, a side edge 200 of the insulation layer 104 is at least 80 micrometers from a die edge 202 of the die 102. In addition, a corner edge 204 of the insulation layer 104 is at least 300 micrometers from a corner 206 of the die 102. However, it will be recognized that any suitable distances may be employed.

The anchor structure 116 may be arranged around (e.g., surrounding) the bump apertures 114 as generally identified at 208. The anchor structure 116 may also be arranged along a perimeter (or a portion thereof) of the insulation layer 104 as generally identified at 210.

In some embodiments, the apertures 118 of the anchor structure 116 are at least 40 micrometers in diameter. In addition, the apertures 118 may be spaced at least 60 micrometers apart when arranged along the perimeter of the insulation layer 104. Furthermore, the apertures 118 may be spaced at least 25 micrometers from an edge of the bump apertures 114 as generally identified at 212. However, it will be recognized that any suitable size and spacing may be employed.

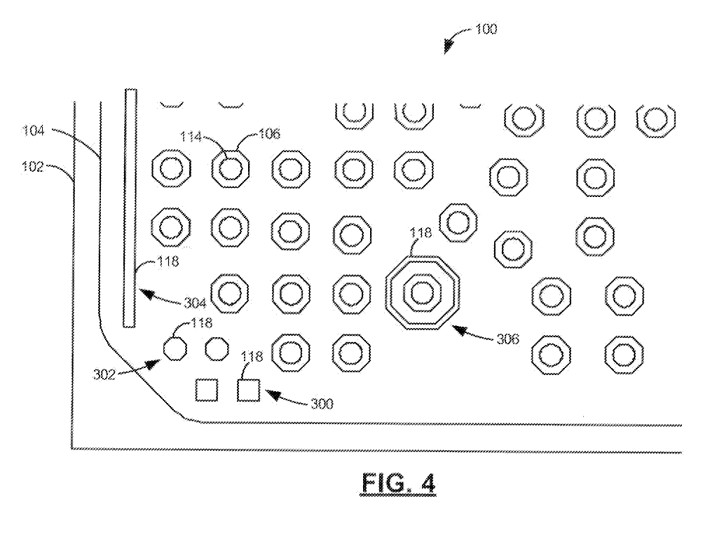

Referring now to FIG. 4, a second exemplary top view of the flip-chip 100 is depicted. The apertures 118 of the anchor structure 116 may be of any suitable shape and size. For example, the aperture 118 may be in the shape of a square as generally identified at 300. The aperture 118 may be generally circular in nature such as in the shape of an octagon generally identified at 302. The aperture 118 may be in the shape of a rectangle or strip as generally identified at 304. In addition, the aperture 118 may circumscribe (or at least substantially circumscribe) the bump aperture 114 as generally identified at 306. Although exemplary shapes of the apertures 118 have been depicted, skilled artisans will appreciate that the apertures 118 may be of any suitable shape.

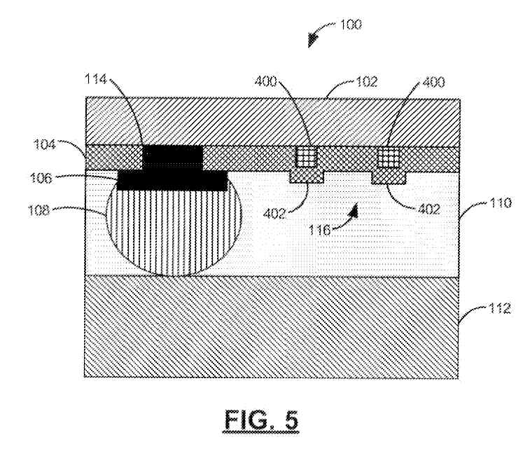

Referring now to FIG. 5, a second embodiment of the flip-chip 100 is depicted. In this embodiment, the anchor structure 116 is defined by a dummy material 400 between the die 102 and the insulation layer 104. The dummy material 400 may be made of copper, aluminum, or any other suitable metal and/or material. In some embodiments, the dummy material 400 is approximately 5 micrometers thick and 40 micrometers wide although other widths and thicknesses are contemplated. The dummy material may be applied using known techniques such as sputtering, plating, or other suitable techniques. The dummy material 400 creates a protrusion 402 in the insulation layer 104, which allows the underfill material 110 to mechanically attach and lock to the insulation layer 104. In some embodiments, the dummy material 400 may have a portion removed to create a recess in the insulation layer 104 rather than the protrusion 402.

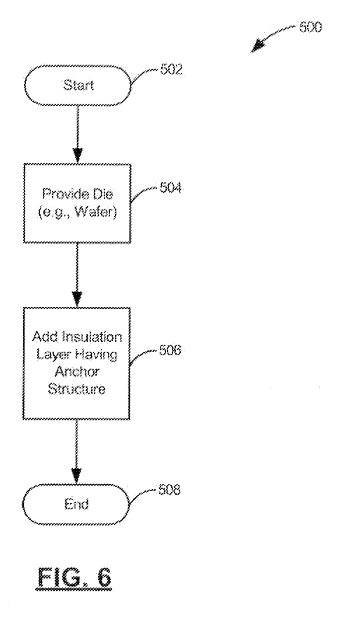

Referring now to FIG. 6, a flowchart depicting exemplary steps that may be taken to make an integrated circuit product having the anchor structure 116 are generally identified at 500. The process starts in step 502. In step 504, the die 102 is provided to an assembly station (not shown) such as by a machine, person or any suitable means as known in the art. In some embodiments, the die 102 may be in wafer form. The assembly station may be anything suitable to hold the die 102 in place during assembly. In step 506, the insulation layer 104, which includes the anchor structure 116, is added to the die 102. As previously discussed, the anchor structure 116 may include apertures 118, protrusions 402, and/or recesses.

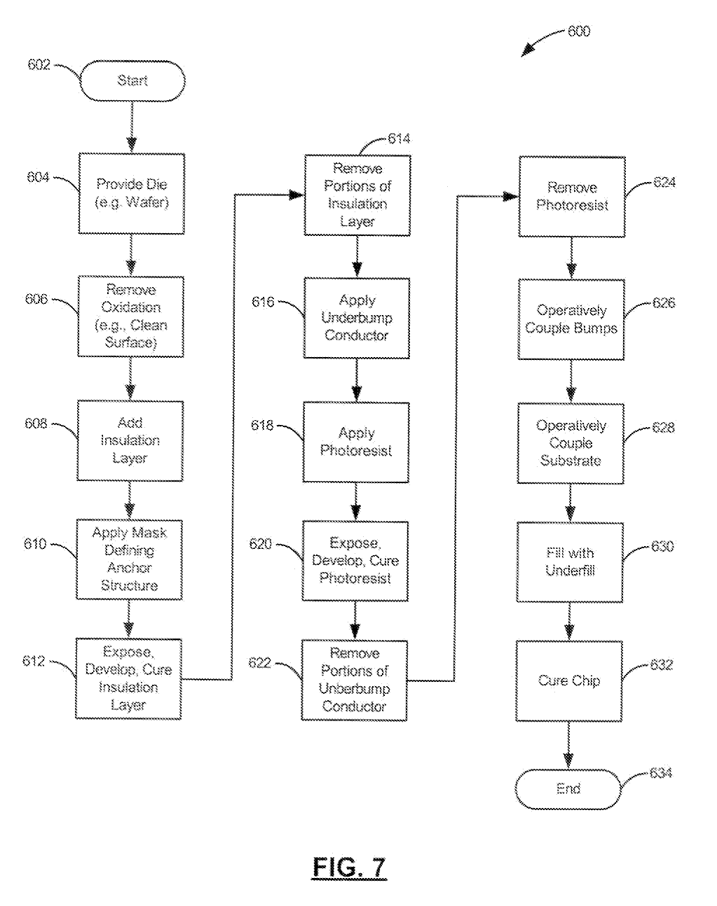

Referring now to FIG. 7, a flowchart depicting exemplary steps that may be taken to make the flip-chip 100 with the anchor structure 116 having apertures 118 are generally identified at 600. The process starts in step 602. In step 604, the die 102, which may be in wafer form, is provided to the assembly station. The insulation layer 104 having the anchor structure 116 may be added to the die 102 as shown, for example, in steps 608-614. However, any suitable process may be used. In step 606, oxidation, which forms on a surface of the die 102 and acts as an insulator, is removed from selected portions of the die 102.

In step 608, the insulation layer 104 is added to the die 102. More specifically, the insulation layer 104 is applied to the die 102 by spin coating as is commonly known in the art. In step 610, a mask that defines the bump aperture 114 and aperture 118 is applied to the insulation layer 104. The mask may be applied to the insulation layer 104 in any manner known in the art. For example, the mask may make contact with the insulation layer 104, the mask may be within close proximity of the insulation layer 104, or the mask may be projected onto the insulation layer 104.

In step 612, the insulation layer 104 is exposed to electromagnetic (EM) radiation, developed, and cured as is commonly known in the art. The EM radiation is typically in the ultraviolet spectrum. In step 614, portions of insulation layer 104 unexposed to the EM radiation through the mask are removed by techniques known in the art to create the bump aperture 114 and aperture 118.

In step 616, underbump conductor is applied to the insulation layer 104 by techniques known in the art. In step 618, photoresist is applied to the underbump conductor. In step 620, the photoresist is exposed to EM radiation, developed, and cured by techniques known in the art to create an underbump layer. When the photoresist is a positive photoresist, the photoresist becomes more soluble when exposed to the EM radiation. However, when the photoresist is a negative photoresist, the photoresist exposed to the EM radiation becomes less soluble. In step 622, portions of the underbump layer are removed by etching or other suitable techniques to create the UBM 106. In step 624, the photoresist is removed.

In step 626, the conductive bump 108 is operatively coupled to the die 102. More specifically, the UBM 106 is operatively coupled to the die 102 through the bump aperture 114 using known techniques and the conductive bump 108 is operatively coupled to the UBM 106 using known techniques. In step 628, the substrate 112 is operatively coupled to the conductive bump 108 using known techniques.

In step 630, the underfill material 110 is filled between the insulation layer 104 and the substrate 112 using known techniques. In this manner, the underfill material 110 flows into the aperture 118 mechanically attaching and locking to the anchor structure 116. This mechanical lock makes the flip-chip 100 less susceptible to delamination. The flip-chip 100 is cured using known techniques in step 632 and the process ends in step 634.

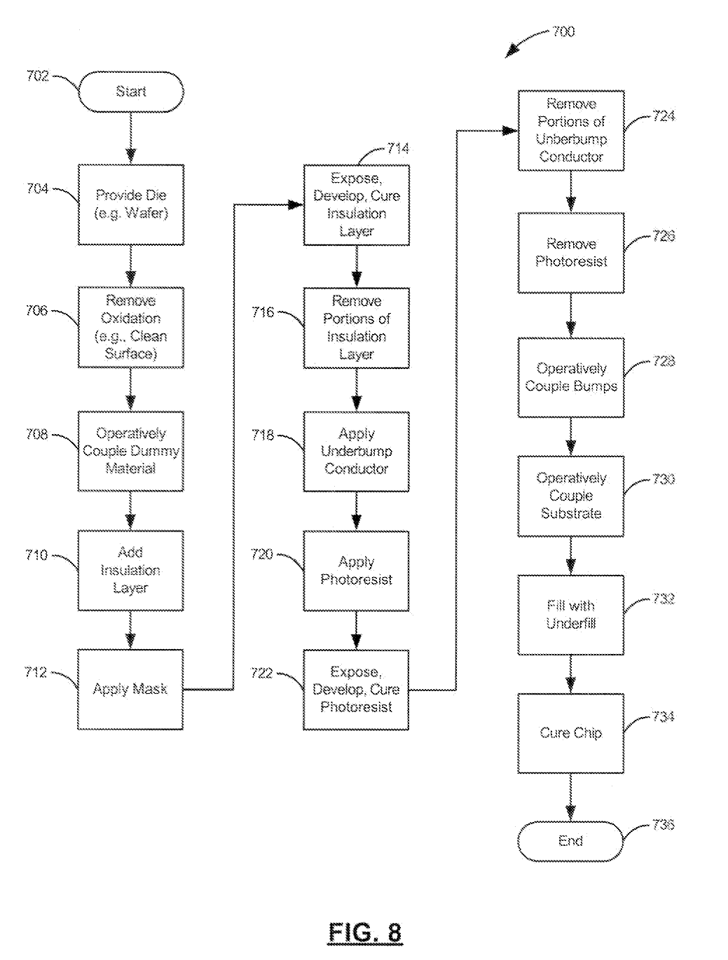

Referring now to FIG. 8, a flowchart depicting exemplary steps that may be taken to make the flip-chip 100 with the anchor structure 116 defined by the dummy material 400 are generally identified at 700. The process starts in step 702. In step 704, the die 102, which may be in wafer form, is provided to the assembly station. In step 706, oxidation that forms on a surface of the die 102 is removed from selected portions of the die 102. In step 708, the dummy material 400 is operatively coupled to the die 102 using known techniques. As previously discussed, the dummy material 400 may be made of copper, aluminum, or any other suitable metal and/or material.

In step 710, the insulation layer 104 is added to the die 102. More specifically, the insulation layer 104 is applied to the die 102 and the dummy material 400 by spin coating or other suitable techniques. In step 716, a mask that defines the bump aperture 114 is applied to the insulation layer 104. In some embodiments, the mask may define both the bump aperture 114 and the aperture 118. The mask may be applied to the insulation layer 104 in any manner known in the art. For example, the mask may make contact with the insulation layer 104, the mask may be within close proximity of the insulation layer 104, or the mask may be projected onto the insulation layer 104.

In step 714, the insulation layer 104 is exposed to EM radiation, developed, and cured using known techniques. The EM radiation is typically in the ultraviolet spectrum. In step 716, portions of the insulation layer 104 unexposed to the EM radiation through the mask are removed to create the bump aperture 114. In embodiments where the mask defines both the bump aperture 114 and the aperture 118, portions of the insulation layer 104 unexposed to the EM radiation are removed to create the bump aperture 114 and aperture 118.

In step 718, underbump conductor is applied to the insulation layer 104 by techniques known in the art. In step 720, photoresist is applied to the underbump conductor. In step 722, the photoresist is exposed to EM radiation, developed, and cured by techniques known in the art to create an underbump layer. When the photoresist is a positive photoresist, the photoresist becomes more soluble when exposed to the EM radiation. However, when the photoresist is a negative photoresist, the photoresist exposed to the EM radiation becomes less soluble. In step 724, portions of the underbump layer are removed by etching or other suitable techniques to create the UBM 106. In step 726, the photoresist is removed.

In step 728, the conductive bump 108 is operatively coupled to the die 102. More specifically, the UBM 106 is operatively coupled to the die 102 through the bump aperture 114 using known techniques and the conductive bump 108 is operatively coupled to the UBM 106 using known techniques. In step 730, the substrate 112 is operatively coupled to the conductive bump 108 using known techniques. In step 732, the underfill material 110 is filled between the insulation layer 104 and the substrate 112. In this manner, the underfill material 110 flows in between the protrusion 402 (or into the recess) mechanically attaching and locking to the anchor structure 116. This mechanical lock makes the flip-chip 100 less susceptible to delamination. The flip-chip 100 is cured using known techniques in step 734 and the process ends in step 736.

It will be recognized that the steps may be performed in any suitable order and that other fabrication techniques may be employed as desired.

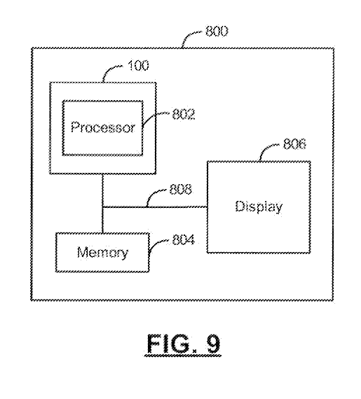

Referring now to FIG. 9, the flip-chip 100 may be implemented in a device 800 such as a wireless phone, a mobile and/or stationary computer, a printer, a LAN interface (wireless and/or wired), a media player, a video decoder and/or encoder, and/or any other suitable device. The device 800 may include, among other things, a processor 802 such as a graphics processor (or core) and/or one or more central processing units (or cores) or any suitable circuitry. The processor 802 may be implemented in the flip-chip 100. More specifically, the die 102 of the flip-chip 100 may include the processor 802.

The device 800 may also include memory 804 such as RAM, ROM, static, discrete logic, dynamic, low latency nonvolatile memory such as flash and/or any suitable optical magnetic or electronic data storage that stores executable instructions that may be executed by one or more processors 802. The memory 804 may also include non local memory such as networked memory available via an intranet server, Internet server or any suitable non local memory. Although not depicted, the memory 804 may also be implemented in the flip-chip 100.

The device 800 may also include a display 806 and/or any other suitable circuits, interfaces, structures or functional operations. The processor 802, memory 804, and/or display 806 may communicate via a bus 808 and/or any other suitable communication mechanism whether the bus is local, wireless, a network connection or any suitable link.

As noted above, the flip-chip 100, among other advantages, has an improved insulation layer that includes an anchor structure. The underfill material mechanically attaches to anchor structure creating a mechanical lock. The mechanical lock makes the structure of the flip-chip 100 stronger and therefore less susceptible to delamination. The apertures, recesses or protrusions of the anchor structure are located at predetermined locations in the insulation layer as determined by a mask layer for example. Also, the size of the apertures, recesses or protrusions are on the multiple micron level as opposed to a submicron level.

While this disclosure includes particular examples, it is to be understood that the disclosure is not so limited. Numerous modifications, changes, variations, substitutions and equivalents will occur to those skilled in the art without departing from the spirit and scope of the present disclosure upon a study of the drawings, the specification and the following claims.

What is claimed is:

1. An integrated circuit (IC) product, comprising:
a die; and
an insulation layer, operatively coupled to the die, that includes a plurality of bump apertures and an underfill anchor structure.

2. The IC product of claim 1 further comprising an underfill material mechanically attached to the underfill anchor structure.

3. The IC product of claim 1 wherein the underfill anchor structure comprises at least one aperture defined by the insulation layer.

4. The IC product of claim 1 wherein the underfill anchor structure comprises at least one of: a protrusion and a recess.

5. The IC product of claim 1 further comprising a dummy material operatively coupled between the die and the insulation layer, wherein the dummy material defines the underfill anchor structure.

6. The IC product of claim 1 wherein the underfill anchor structure is configured along at least a portion of a perimeter of the insulation layer.

7. The IC product of claim 1 wherein the underfill anchor structure is configured around the plurality of bump apertures.

8. A process of making an integrated circuit product, comprising:
providing a die; and
adding an insulation layer to the die, wherein the insulation layer includes a plurality of bump apertures and an underfill anchor structure.

9. The process of claim 8 wherein at least one of the plurality of bump apertures and the underfill anchor structure is formed by removing a portion of the insulation layer.

10. The process of claim 9 wherein the portion of the insulation layer is removed by:
applying a mask to the insulation layer, wherein the mask defines the at least one of: the plurality of bump apertures and the anchor structure; and
exposing electromagnetic radiation to the mask and to the insulation layer;
developing the insulation layer;
curing the insulation layer; and
removing portions of the insulation layer unexposed to the electromagnetic radiation through the mask.

11. The process of claim 8 wherein the underfill anchor structure includes at least one aperture defined by the insulation layer.

12. The process of claim 8 wherein the underfill anchor structure includes at least one of: a protrusion and a recess.

13. The process of claim 8 wherein the underfill anchor structure is configured along at least a portion of a perimeter of the insulation layer.

14. The process of claim 8 wherein the underfill anchor structure is configured around the plurality of bump apertures.

15. The process of claim 8 further comprising operatively coupling a dummy material to the die surface prior to adding the insulation layer, wherein the dummy material defines the underfill anchor structure.

16. The process of claim 8 further comprising operatively coupling a plurality of conductive bumps to the die through the plurality of bump apertures.

17. The process of claim 16 further comprising operatively coupling a substrate to the plurality of conductive bumps.

18. The process of claim 17 further comprising filling gaps between the die and the substrate with an underfill material, wherein the underfill material is mechanically attached to the underfill anchor structure.

19. An integrated circuit (IC) product, comprising:
a die;
an insulation layer, operatively coupled to the die, that includes a plurality of bump apertures and an underfill anchor structure;
a plurality of conductive bumps operatively coupled to the die through the plurality of bump apertures;
a substrate operatively coupled to the plurality of conductive bumps; and
an underfill material that fills in gaps between the die and the substrate, wherein the underfill material is mechanically attached to the underfill anchor structure.

20. The IC product of claim 19 wherein the underfill anchor structure comprises at least one aperture defined by the insulation layer.

21. The IC product of claim 19 wherein the underfill anchor structure comprises at least one of: a protrusion and a recess.

22. The IC product of claim 19 wherein the underfill anchor structure is configured along at least a portion of a perimeter of the insulation layer.

23. The IC product of claim 19 wherein the underfill anchor structure is configured around the plurality of bump apertures.

24. A device comprising:
an integrated circuit product comprising:
a die;
an insulation layer, operatively coupled to the die, that includes a plurality of bump apertures and an underfill anchor structure;
a plurality of conductive bumps operatively coupled to the die through the plurality of bump apertures;
a substrate operatively coupled to the plurality of conductive bumps; and
an underfill material that fills in gaps between the die and the substrate, wherein the underfill material is mechanically attached to the underfill anchor structure.

25. The device of claim 24 further comprising a display operatively coupled to the integrated circuit product, wherein the die comprises a processor.
